(19) United States
(12) Patent Application Publication
(10) Pub. No.: US 2023/0077403 A1
(43) Pub. Date: Mar. 16, 2023

(54) MULTI-ELECTRON BEAM IMAGE ACQUISITION APPARATUS, AND MULTI-ELECTRON BEAM IMAGE ACQUISITION METHOD

(71) Applicant: NuFlare Technology, Inc., Yokohama-shi (JP)

(72) Inventors: Kazuhiko INOUE, Yokohama-shi (JP); Munehiro OGASAWARA, Hiratsuka-shi (JP)

(73) Assignee: NuFlare Technology, Inc., Yokohama-shi (JP)

(21) Appl. No.: 18/056,810

(22) Filed: Nov. 18, 2022

Related U.S. Application Data
(63) Continuation of application No. PCT/JP2021/015551, filed on Apr. 15, 2021.

(30) Foreign Application Priority Data
Jun. 12, 2020 (JP) 2020-102169

(51) Int. Cl. H01J 37/317; H01J 37/141; H01J 37/05; H01J 37/244

(52) U.S. Cl. CPC H01J 37/3177; H01J 37/1413; H01J 37/05; H01J 37/244

(57) ABSTRACT

A multi-electron beam image acquisition apparatus includes a multiple-beam forming mechanism to form multiple primary electron beams, a primary-electron optical system to irradiate 1a sample with the multiple primary electron beams, a beam separator, arranged at a position conjugate to an image plane of each of the multiple primary electron beams, to form an electric field and a magnetic field to be mutually perpendicular, to separate multiple secondary electron beams, emitted from the sample due to irradiation with the multiple primary electron beams, from the multiple primary electron beams by using actions of the electric field and the magnetic field, and to have a lens action on the multiple secondary electron beams in at least one of the electric field and the magnetic field, a multi-detector to detect the multiple secondary electron beams, and a secondary-electron optical system to lead the multiple secondary electron beams to the multi-detector.

### CROSS-REFERENCE TO RELATED APPLICATION

This application is a continuation application based upon and claims the benefit of priority from prior Japanese Patent Application No. 2020-102169 (application number) filed on Jun. 12, 2020 in Japan, and International Application PCT/JP2021/015551, the International Filing Date of which is Apr. 15, 2021. The contents described in JP2020-102169 and PCT/JP2021/015551 are incorporated herein by reference.

### BACKGROUND OF THE INVENTION

### Field of the Invention

Embodiments of the present invention relate to a multi-electron beam image acquisition apparatus, and a multi-electron beam image acquisition method. For example, embodiments of the present invention relate to a method for acquiring an image of a pattern on a substrate by using multiple electron beams.

### Description of Related Art

With recent progress in high integration and large capacity of the LSI (Large Scale Integrated circuits), the line width (critical dimension) required for circuits of semiconductor elements is becoming increasingly narrower. Such semiconductor elements are manufactured through circuit forming processing by exposing and transferring a pattern onto a wafer by means of a reduced projection exposure apparatus known as a stepper, using an original or “master” pattern (also called a mask or a reticle, hereinafter generically referred to as a mask) on which a circuit pattern has been formed.

LSI manufacturing requires an enormous production cost, therefore, it is essential to improve the yield. However, as typified by 1 gigabit DRAMs (Dynamic Random Access Memories), the size of patterns that make up the LSI becomes the order of nanometers from submicrons. Also, in recent years, with miniaturization of dimensions of LSI patterns formed on a semiconductor wafer, dimensions to be detected as a pattern defect have become extremely small. Therefore, the pattern inspection apparatus which inspects defects of ultrafine patterns exposed and transferred onto a semiconductor wafer needs to be highly accurate. Further, one of major factors that decrease the yield is due to pattern defects on the mask used for exposing and transferring ultrafine patterns onto a semiconductor wafer by the photolithography technology. Therefore, the pattern inspection apparatus for inspecting defects on an exposure transfer mask used in manufacturing LSI needs to be highly accurate.

The inspection apparatus acquires a pattern image by, for example, irradiating an inspection target substrate with multiple electron beams and detecting a secondary electron corresponding to each beam emitted from the inspection target substrate. As an inspection method, there is known a method of comparing a measured image acquired by imaging a pattern formed on a substrate with design data or with another measured image acquired by imaging an identical pattern on the same substrate. For example, as a pattern inspection method, there is “die-to-die inspection” or “die-to-database inspection”. Specifically, the “die-to-die inspection” method compares data of measured images acquired by imaging identical patterns at different positions on the same substrate. The “die-to-database inspection” method generates, based on pattern design data, design image data (reference image), and compares it with a measured image being measured data acquired by imaging a pattern. Acquired images are transmitted as measured data to a comparison circuit. After performing alignment between images, the comparison circuit compares the measured data with reference data according to an appropriate algorithm, and determines that there is a pattern defect if the compared data do not match each other.

In the case of acquiring an inspection image by using multiple electron beams, an E×B (E cross B) filter (which makes the electron field and the magnetic field be orthogonal) is arranged on the trajectory of a primary electron beam to separate a secondary electron. In order to improve image accuracy, it is desirable to narrow the diameter of the beam irradiating the surface of the target object. Therefore, the E×B filter is arranged on the position conjugate to the image plane of the primary electron beam where the influence of E×B is small. With respect to a primary electron beam and a secondary electron beam, the energy of a primary electron incident on the surface of the target object is different from that of a generated secondary electron. Therefore, when a primary electron beam is focused (converged) on the E×B filter, a secondary electron spreads without converging on the E×B filter. Thus, the secondary electron separated by the E×B filter continues spreading in the detection optical system. For this reason, aberration occurring in the detection optical system becomes large, and there is a problem that multiple secondary electron beams may overlap with each other on the detector. This problem is not limited to the inspection apparatus, and may similarly occur in the apparatus in general which acquires an image by using multiple electron beams.

There is disclosed a method in which a Wien filter of four-stage multipole lens for correcting an on-axis chromatic aberration is arranged in the secondary electron optical system away from the primary electron optical system in order to correct the on-axis chromatic aberration of a separated secondary electron (e.g., refer to Japanese Patent Application Laid-open (JP-A) No. 2006-244875).

### BRIEF SUMMARY OF THE INVENTION

According to one aspect of the present invention, a multi-electron beam image acquisition apparatus includes

a multiple beam forming mechanism configured to form multiple primary electron beams,

a primary electron optical system configured to irradiate a target object surface with the multiple primary electron beams,

a beam separator, arranged at a position conjugate to an image plane of each primary electron beam of the multiple primary electron beams, configured to form an electric field and a magnetic field to be perpendicular to each other, to separate multiple secondary electron beams, emitted from the target object surface due to irradiation with the multiple primary electron beams, from the multiple primary electron beams by using actions of the electric field and the magnetic field, and to have a lens action on the multiple secondary electron beams in at least one of the electric field and the magnetic field,

a multi-detector configured to detect the multiple secondary electron beams, and

a secondary electron optical system configured to lead the multiple secondary electron beams to the multi-detector.

According to another aspect of the present invention, a multi-electron beam image acquisition method includes

irradiating a target object surface with multiple primary electron beams,

separating, at a position conjugate to an image plane of each primary electron beam of the multiple primary electron beams, multiple secondary electron beams, which were emitted from the target object surface due to the irradiating with the multiple primary electron beams, from the multiple primary electron beams, and refracting the multiple secondary electron beams in a converging direction at the position conjugate to the image plane,

further refracting the multiple secondary electron beams which have been separated from the multiple primary electron beams and refracted in the converging direction at the position conjugate to the image plane, in the converging direction at a position away from a trajectory of the multiple primary electron beams, and

detecting the multiple secondary electron beams which have been refracted at the position away from the trajectory of the multiple primary electron beams.

### BRIEF DESCRIPTION OF THE DRAWINGS

FIG. 1 is a configuration diagram of a pattern inspection apparatus according to a first embodiment;

FIG. 2 is a conceptual diagram of a configuration of a shaping aperture array substrate according to the first embodiment;

FIGS. 3A and 3B are illustrations of a configuration of a beam separator according to the first embodiment;

FIG. 4 is an illustration for explaining a relation between a magnetic field and an electric field generated by a beam separator according to the first embodiment;

FIG. 5 is an illustration for explaining an electric field generated by a multipolar electrode according to the first embodiment;

FIG. 6 is an illustration of examples of center beam trajectories according to the first embodiment and a comparative example;

FIG. 7 is an illustration of an example of a trajectory of multiple secondary electron beams according to a comparative example of the first embodiment;

FIG. 8 is an illustration of an example of a trajectory of multiple secondary electron beams according to the first embodiment;

FIG. 9 is an illustration of an example of beam diameters of multiple secondary electron beams at the detection surface of a multi-detector according to the first embodiment and a comparative example;

FIG. 10 is an example of a plurality of chip regions formed on a semiconductor substrate, according to the first embodiment;

FIG. 11 is an illustration describing image acquisition processing according to the first embodiment; and

FIG. 12 is an illustration of a configuration of a beam separator according to a second embodiment.

### DETAILED DESCRIPTION OF THE INVENTION

Embodiments below describe an apparatus and method that can suppress spreading of multiple secondary electron beams separated from multiple primary electron beams.

Embodiments below describe a multi-electron beam inspection apparatus as an example of a multi-electron beam image acquisition apparatus. However, the image acquisition apparatus is not limited to the inspection apparatus, and any apparatus is acceptable as long as it acquires an image by using multiple beams.

### First Embodiment

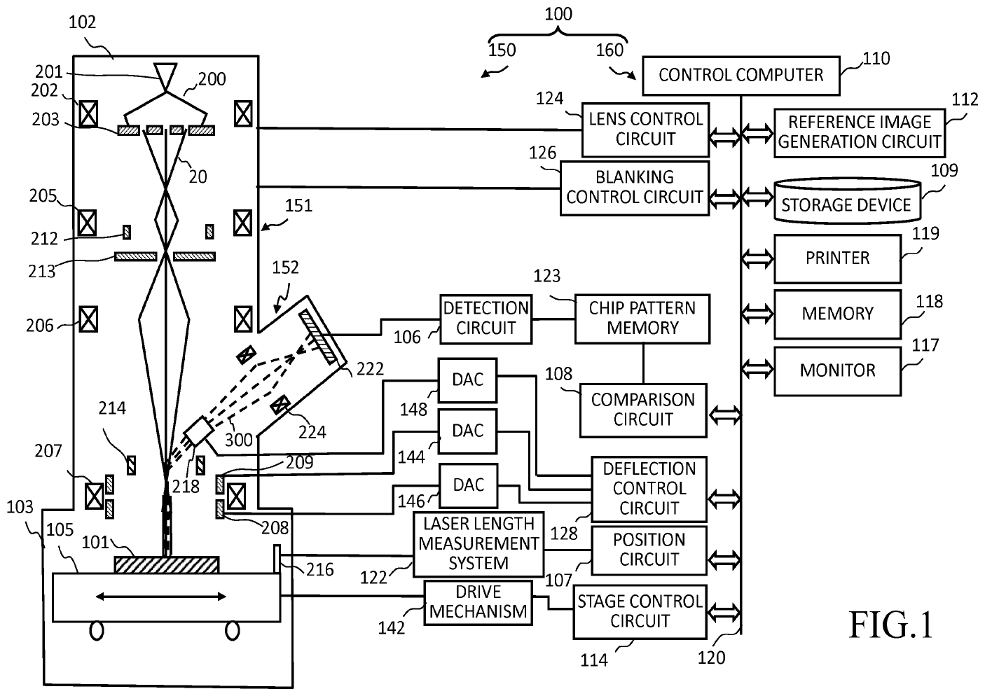

FIG. 1 is a configuration diagram of a pattern inspection apparatus according to a first embodiment. In FIG. 1, an inspection apparatus 100 for inspecting patterns formed on the substrate is an example of a multi-electron beam inspection apparatus. The inspection apparatus 100 includes an image acquisition mechanism 150 and a control system circuit 160 (control unit). The image acquisition mechanism 150 includes an electron beam column 102 (electron optical column), an inspection chamber 103, a detection circuit 106, a chip pattern memory 123, a stage drive mechanism 142, and a laser length measurement system 122. In the electron beam column 102, there are arranged an electron gun 201, an electromagnetic lens 202, a shaping aperture array substrate 203, an electromagnetic lens 205, a collective deflector 212, a limiting aperture substrate 213, electromagnetic lenses 206 and 207, a main deflector 208, a sub deflector 209, a beam separator 214, a deflector 218, an electromagnetic lens 224, and a multi-detector 222.

A primary electron optical system 151 is composed of the electron gun 201, the electromagnetic lens 202, the shaping aperture array substrate 203, the electromagnetic lens 205, the collective deflector 212, the limiting aperture substrate 213, the electromagnetic lens 206, the electromagnetic lens 207 (objective lens), the main deflector 208, and the sub deflector 209. A secondary electron optical system 152 is composed of the deflector 218, and the electromagnetic lens 224. The beam separator 214 includes a function of an E×B filter (or also called an E×B deflector).

In the inspection chamber 103, there is disposed a stage 105 movable at least in the x and y directions. The substrate 101 (target object) to be inspected is mounted on the stage 105. The substrate 101 may be an exposure mask substrate, or a semiconductor substrate such as a silicon wafer. In the case of the substrate 101 being a semiconductor substrate, a plurality of chip patterns (wafer dies) are formed on the semiconductor substrate. In the case of the substrate 101 being an exposure mask substrate, a chip pattern is formed on the exposure mask substrate. The chip pattern is composed of a plurality of figure patterns. When the chip pattern formed on the exposure mask substrate is exposed/transferred onto the semiconductor substrate a plurality of times, a plurality of chip patterns (wafer dies) are formed on the semiconductor substrate. The case of the substrate 101 being a semiconductor substrate is mainly described below. The substrate 101 is placed, with its pattern-forming surface facing upward, on the stage 105, for example. Further, on the stage 105, there is disposed a mirror 216 which reflects a laser beam for measuring a laser length emitted from the laser length measurement system 122 arranged outside the inspection chamber 103.

The multi-detector 222 is connected, at the outside of the electron beam column 102, to the detection circuit 106. The detection circuit 106 is connected to the chip pattern memory 123.

In the control system circuit 160, a control computer 110 which controls the whole of the inspection apparatus 100 is connected, through a bus 120, to a position circuit 107, a comparison circuit 108, a reference image generation circuit 112, a stage control circuit 114, a lens control circuit 124, a blanking control circuit 126, a deflection control circuit 128, a storage device 109 such as a magnetic disk drive, a monitor 117, a memory 118, and a printer 119. The deflection control circuit 128 is connected to DAC (digital-to-analog conversion) amplifiers 144, 146 and 148. The DAC amplifier 146 is connected to the main deflector 208, and the DAC amplifier 144 is connected to the sub deflector 209. The DAC amplifier 148 is connected to the deflector 218.

The chip pattern memory 123 is connected to the comparison circuit 108. The stage 105 is driven by the drive mechanism 142 under the control of the stage control circuit 114. In the drive mechanism 142, a drive system such as a three (x-, y-, and θ-) axis motor which provides drive in the directions of x, y, and θ in the stage coordinate system is configured, and therefore, the stage 105 can be moved in the x, y, and θ directions. A step motor, for example, can be used as each of these x, y, and θ motors (not shown). The stage 105 is movable in the horizontal direction and the rotation direction by the x-, y-, and θ-axis motors. The movement position of the stage 105 is measured by the laser length measurement system 122, and supplied (transmitted) to the position circuit 107. Based on the principle of laser interferometry, the laser length measurement system 122 measures the position of the stage 105 by receiving a reflected light from the mirror 216. In the stage coordinate system, the x, y, and θ directions are set, for example, with respect to a plane perpendicular to the optical axis of the multiple primary electron beams 20.

The electromagnetic lenses 202, 205, 206, 207, and 224, and the beam separator 214 are controlled by the lens control circuit 124. The collective deflector 212 is composed of two or more electrodes (or poles), and each electrode is controlled by the blanking control circuit 126 through a DAC amplifier (not shown). The sub deflector 209 is composed of four or more electrodes (or poles), and each electrode is controlled by the deflection control circuit 128 through the DAC amplifier 144. The main deflector 208 is composed of four or more electrodes (or poles), and each electrode is controlled by the deflection control circuit 128 through the DAC amplifier 146. The deflector 218 is composed of four or more electrodes (or poles), and each electrode is controlled by the deflection control circuit 128 through the DAC amplifier 148.

To the electron gun 201, there is connected a high voltage power supply circuit (not shown). The high voltage power supply circuit applies an acceleration voltage between a filament and an extraction electrode (which are not shown) in the electron gun 201. In addition to applying the acceleration voltage, a voltage is applied to a predetermined extraction electrode (Wehnelt), and the cathode is heated to a predetermined temperature, and thereby, electrons from the cathode are accelerated to be emitted as an electron beam 200.

FIG. 1 shows configuration elements necessary for describing the first embodiment. It should be understood that other configuration elements generally necessary for the inspection apparatus 100 may also be included therein.

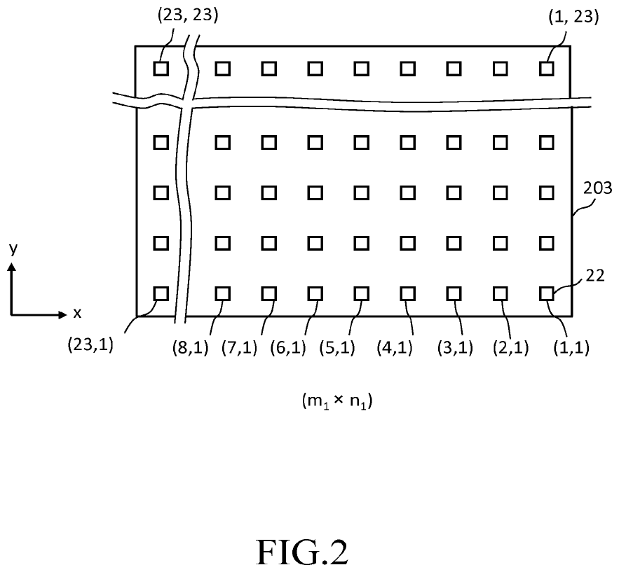

FIG. 2 is a conceptual diagram of a configuration of a shaping aperture array substrate according to the first embodiment. As shown in FIG. 2, holes (openings) 22 of m₁ rows long (length in the y direction) (each row in the x direction) and n₁ columns wide (width in the x direction) (each column in the y direction) are two-dimensionally formed at a predetermined arrangement pitch in the shaping aperture array substrate 203, where m₁ and n₁ are integers of 2 or more. In the case of FIG. 2, holes (openings) 22 of 23×23 are formed. Each of the holes 22 is a rectangle (including a square) having the same dimension, shape, and size. Alternatively, each of the holes 22 may be a circle with the same outer diameter. Multiple primary electron beams 20 are formed by letting portions of the electron beam 200 individually pass through a corresponding one of a plurality of holes 22. The shaping aperture array substrate 203 is an example of a multiple beam forming mechanism which forms multiple primary electron beams.

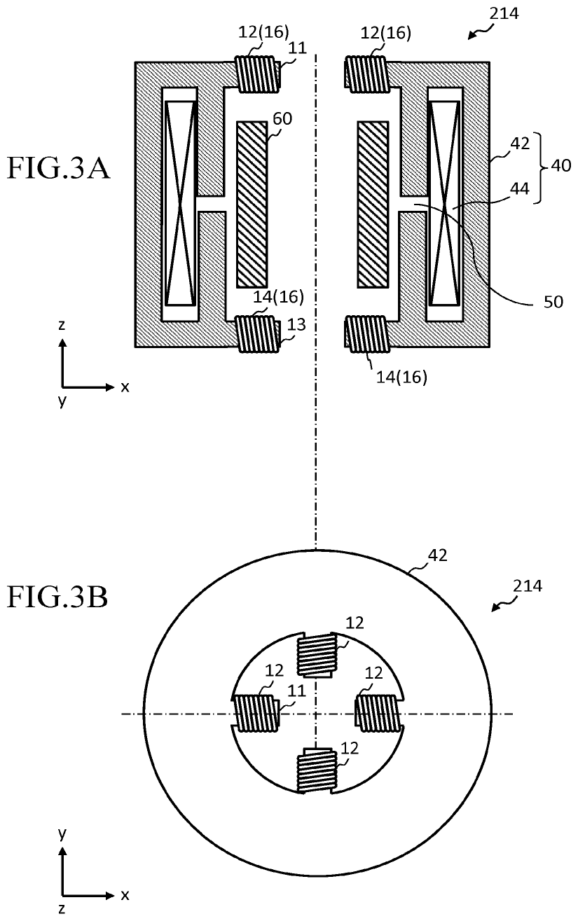

FIGS. 3A and 3B are illustrations of a configuration of a beam separator according to the first embodiment. FIG. 3A is a sectional view of the beam separator 214 of the first embodiment. FIG. 3B is a top view of the beam separator 214 of the first embodiment. In FIGS. 3A and 3B, the beam separator 214 includes magnetic lenses 40, a set of magnetic poles 16, and a set of electrodes 60. The set of magnetic poles 16 is configured by two or more poles. In the cases of FIG. 3A and FIG. 3B, the set of magnetic poles 16 is composed of two stages of a set of multipolar magnetic poles 12 and a set of multipolar magnetic poles 14. The magnetic lens 40 is composed of a coil 44 disposed surrounding the trajectory central axis of the multiple primary electron beams 20 and the multiple secondary electron beams 300, and a pole piece (yoke) 42 surrounding the coil 44. The pole piece 42 is configured by a magnetic material, such as iron, for example. In the pole piece 42, a gap 50 (opening) (also called a crevice) for leaking high-density magnetic field lines made by the coil 44 toward the trajectory central axis side of the multiple primary electron beams 20 and the multiple secondary electron beams 300 is formed at the intermediate height position of the pole piece 42. At the upper part of the pole piece 42, a plurality of convex portions 11 projecting toward the inner periphery side are formed. By arranging a coil at each convex portion 11, the set of the multipolar magnetic poles 12, being the first stage, is configured. At the lower part of the pole piece 42, a plurality of convex portions 13 projecting toward the inner periphery side are formed. By arranging a coil at each convex portion 13, the set of the multipolar magnetic poles 14, being the second stage, is configured. The intermediate height position between the set of the multipolar magnetic poles 12, being the first stage, and the set of the multipolar magnetic poles 14, being the second stage, is coincident with the intermediate height position of the magnetic lens 40. In other words, the set of the multipolar magnetic poles 12, being the first stage, and the set of the multipolar magnetic poles 14, being the second stage, are arranged symmetrically at the upper and lower sides with respect to the magnetic field center position formed at the height position of the gap of the magnetic lens 40. Each set of the sets of the multipolar magnetic poles 12 and 14 is composed of two or more poles. In the case of FIG. 3B, it is composed of four magnetic poles with phases mutually shifted by 90 degrees. Desirably, it is composed of eight magnetic poles. Further, the set of electrodes 60 is disposed between the set of multipolar magnetic poles 12 and the set of multipolar magnetic poles 14. The set of electrodes 60 is configured by a non-magnetic material. The set of electrodes 60 is arranged at the intermediate height position between the set of multipolar magnetic poles 12, being the first stage, and the set of multipolar magnetic poles 14, being the second stage. The set of electrodes 60 is composed of two or more electrodes, and for example, of four electrodes with phases mutually shifted by 90 degrees. Desirably, it is composed of eight electrodes.

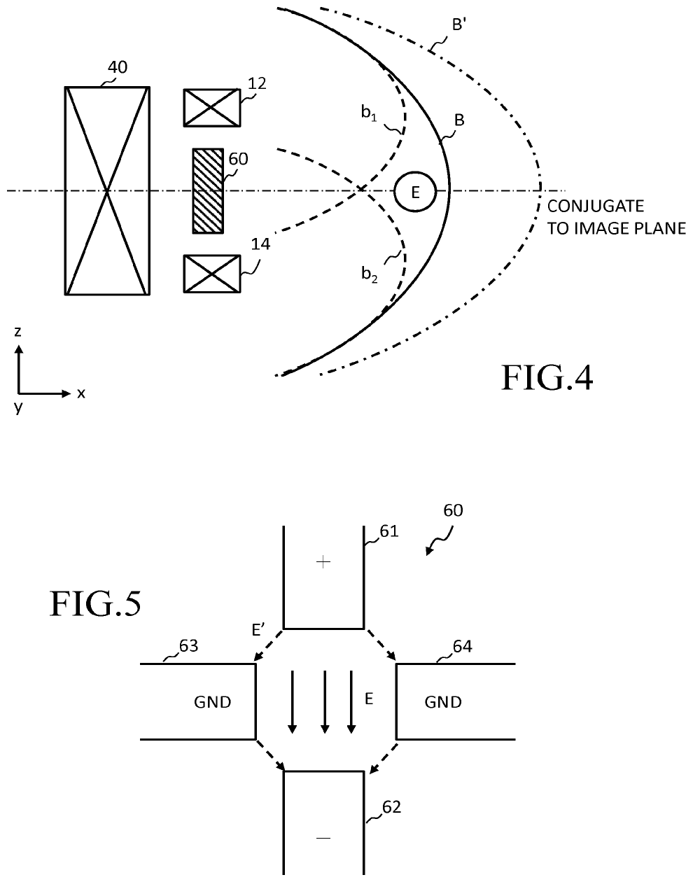

FIG. 4 is an illustration for explaining a relation between a magnetic field and an electric field generated by a beam separator according to the first embodiment. In FIG. 4, a magnetic field b1 whose magnetic field center is at the center height position of the set of multipolar magnetic poles 12 is generated by the set of multipolar magnetic poles 12. A magnetic field b2 whose magnetic field center is at the center height position of the set of multipolar magnetic poles 14 is generated by the set of multipolar magnetic poles 14. By combining these two magnetic fields b1 and b2, a magnetic field B is generated whose magnetic field center is at the intermediate height position between the set of multipolar magnetic poles 12, being the first stage, and the set of multipolar magnetic poles 14, being the second stage. Further, an electric field E whose electric field center is at the intermediate height position of the set of electrodes 60 and whose direction is perpendicular to the magnetic field B is generated by the set of electrodes 60. The intermediate height position of the set of electrodes 60 is coincident with the intermediate height position between the set of multipolar magnetic poles 12, being the first stage, and the set of multipolar magnetic poles 14, being the second stage. Further, a magnetic field B′ whose magnetic field center is at the height position of the gap 50 of the magnetic lens 40 is generated. Thus, the field center positions of the magnetic field B, the electric field E, and the magnetic field B′ are at the same height position (position conjugate to the image plane).

FIG. 5 is an illustration for explaining an electric field generated by a set of multipolar electrodes according to the first embodiment. In FIG. 5, the set of electrodes 60 is composed of four electrodes 61, 62, 63, and 64. With respect to the two opposite electrodes 61 and 62, a positive potential is applied to the electrode 61, and a negative potential is applied to the electrode 62. By this, an electric field whose direction is from the electrode 61 to the electrode 62 is generated. At this time, an electric field parallel to the opposed surfaces of the electrodes 61 and 62 is generated, and furthermore, curved electric fields are generated at the lateral side sides of the electrodes. Therefore, by applying a grand (GND) electric potential to the two opposite electrodes 63 and 64 whose phases are mutually shifted by 90 degrees, the influence of the electric field at the lateral side sides of the electrodes 61 and 62 can be eliminated. Thereby, generated electric fields can be close in shape to the parallel electric field E. Also, by configuring each set of the sets of multipolar magnetic poles 12 and 14 (not shown) by four poles, generated magnetic fields can be close in shape to the parallel magnetic fields b1 and b2.

According to the first embodiment, the height position of the magnetic field center (electric field center) of the beam separator 214 is arranged at the position conjugate to the image plane of the multiple primary electron beams 20. Next, operations of the image acquisition mechanism 150 in the case of acquiring a secondary electron image will be explained.

The image acquisition mechanism 150 acquires an inspection image of a figure pattern formed on the substrate 101 by using multiple electron beams. Hereinafter, operations of the image acquisition mechanism 150 in the inspection apparatus 100 will be explained.

The electron beam 200 emitted from the electron gun 201 (emission source) is refracted by the electromagnetic lens 202, and illuminates the whole of the shaping aperture array substrate 203. As shown in FIG. 2, a plurality of holes 22 (openings) are formed in the shaping aperture array substrate 203. The region including all of the plurality of holes 22 is irradiated by the electron beam 200. The multiple primary electron beams 20 are formed by letting portions of the electron beam 200 applied to the positions of a plurality of holes 22 individually pass through a corresponding one of the plurality of holes 22 in the shaping aperture array substrate 203.

The formed multiple primary electron beams 20 are individually refracted by the electromagnetic lenses 205 and 206, and travel to the electromagnetic lens 207, while repeating forming an intermediate image and a crossover, passing through the beam separator 214 disposed on the intermediate image plane (position conjugate to the image plane: I. I. P.) of each beam of the multiple primary electron beams 20. Further, by disposing the limiting aperture substrate 213 with limited passage holes close to the crossover position of the multiple primary electron beams 20, it becomes possible to block scattered beams. Further, by collectively deflecting all the multiple primary electron beams 20 by the collective deflector 212 and blocking the entire multiple primary electron beams 20 by the limiting aperture substrate 213, it becomes possible to perform blanking of all the multiple primary electron beams 20.

When the multiple primary electron beams 20 are incident on the electromagnetic lens 207 (objective lens), the electromagnetic lens 207 focuses the multiple primary electron beams 20 onto the substrate 101. The multiple primary electron beams 20 having been focused on the substrate 101 (target object) by the objective lens 207 are collectively deflected by the main deflector 208 and the sub deflector 209 to irradiate respective beam irradiation positions on the substrate 101. Thus, this is how the substrate 101 is irradiated with the multiple primary electron beams by the primary electron optical system.

When desired positions on the substrate 101 are irradiated with the multiple primary electron beams 20, a flux of secondary electrons (multiple secondary electron beams 300) including reflected electrons, each corresponding to each of the multiple primary electron beams 20, is emitted from the substrate 101 due to the irradiation with the multiple primary electron beams 20.

The multiple secondary electron beams 300 emitted from the substrate 101 travel to the beam separator 214 through the electromagnetic lens 207. The beam separator 214 is arranged at the position conjugate to the image plane of each primary electron beam of the multiple primary electron beams 20, forms the electric field E and the magnetic field B to be perpendicular to each other, separates the multiple secondary electron beams 300, emitted from the surface of the substrate 101 due to irradiation with the multiple primary electron beams 20, from the multiple primary electron beams 20, using actions of the electric field E and the magnetic field B, and has a lens action on the multiple secondary electron beams 300 in at least one of the electric field E and the magnetic field B. Specifically, it acts as follows:

By the sets of multipolar magnetic poles 12 and 14 and the set of electrodes 60, the beam separator 214 generates the magnetic field B and the electric field E to be perpendicular to each other on the plane (plane of the x and y axes) perpendicular to the traveling direction of the center beam of the multiple primary electron beams 20. The sets of multipolar magnetic poles 12 and 14 and the set of electrodes 60 configure an E×B filter. The electric field E exerts a force in a fixed direction regardless of the traveling direction of electrons. In contrast, the magnetic field B exerts a force according to Fleming's left-hand rule. Therefore, the direction of the force acting on electrons can be changed depending on the entering (or “traveling”) direction of electrons. With respect to the multiple primary electron beams 20 entering the beam separator 214 from above, since the forces due to the electric field and the magnetic field cancel each other out, the beams 20 travel straight downward. In contrast, with respect to the multiple secondary electron beams 300 entering the beam separator 214 from below, since both the forces due to the electric field and the magnetic field are exerted in the same direction, the beams 300 are bent obliquely upward, and separated from the multiple primary electron beams 20.

The multiple secondary electron beams 300 having been bent obliquely upward and separated from the multiple primary electron beams 20 are led to the multi-detector 222 by the secondary electron optical system. Specifically, the multiple secondary electron beams 300 separated from the multiple primary electron beams 20 are further bent by being deflected by the deflector 218, and projected on the multi-detector 222 while being refracted in the converging direction by the electromagnetic lens 224, at the position away from the trajectory of the multiple primary electron beams. The multi-detector 222 (multiple secondary electron beam detector) detects the multiple secondary electron beams 300 having been refracted and projected. The multi-detector 222 includes a plurality of detection elements (e.g., diode type two-dimensional sensor (not shown)). At the detection surface of the multi-detector 222, since each beam of the multiple secondary electron beams 300 collides with a detection element corresponding to each of the multiple secondary electron beams 300, electrons are generated, and secondary electron image data is generated for each pixel. An intensity signal detected by the multi-detector 222 is output to the detection circuit 106. A sub-irradiation region on the substrate 101, which is surrounded by the x-direction beam pitch and the y-direction beam pitch and in which the beam concerned itself is located, is irradiated and scanned with each primary electron beam.

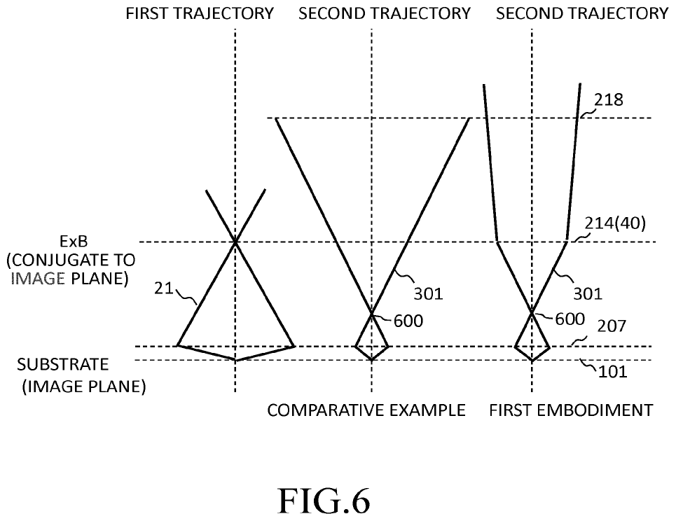

FIG. 6 is an illustration of examples of center beam trajectories according to the first embodiment and a comparative example. In FIG. 6, a center primary electron beam 21 of the multiple primary electron beams 20 spreads after passing through the beam separator 214 which is arranged at the position conjugate to the image plane, and is bent in the converging direction by the magnetic lens 207 and focused on the surface of the substrate 101. The energy at the time when a center secondary electron beam 301 of the multiple secondary electron beams 300 from the substrate 101 is emitted is smaller than the incident energy of the center primary electron beam 21 incident on the substrate 101. Therefore, an image plane 600 is formed at the position before reaching the beam separator 214. Then, the center secondary electron beam 301 travels, while spreading, to the beam separator 214. Here, in the comparative example which uses a simple E×B filter as the beam separator 214, the center secondary electron beam 301 travels, while further spreading, to the deflector 218. In contrast, according to the first embodiment, a lens action is applied to the multiple secondary electron beams 300 by the magnetic lens 40 of the beam separator 214. Therefore, the multiple secondary electron beams 300 is refracted in the converging direction by the magnetic lens 40 arranged at the position conjugate to the image plane of the primary electron beam 21. Accordingly, in the first embodiment, as shown, for example, in FIG. 6, the center secondary electron beam 301 of the multiple secondary electron beams 300 travels, while its spreading is suppressed or prevented, to the deflector 218.

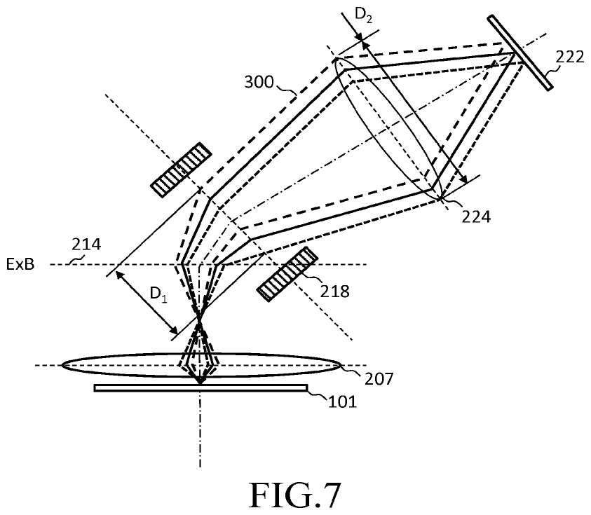

FIG. 7 is an illustration of an example of a trajectory of multiple secondary electron beams according to a comparative example of the first embodiment.

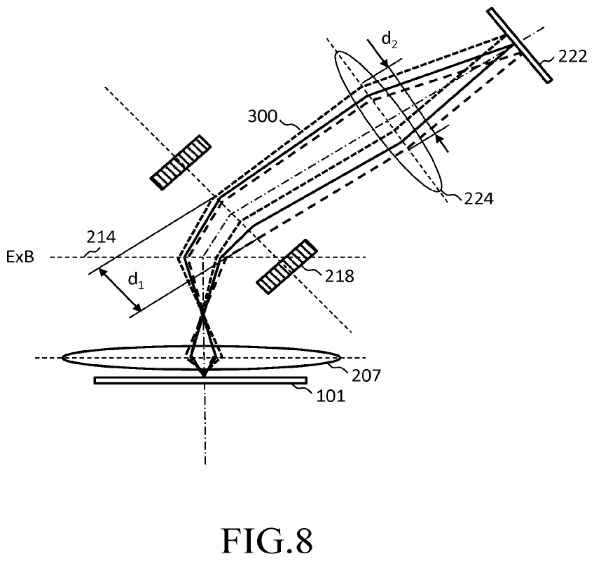

FIG. 8 is an illustration of an example of a trajectory of multiple secondary electron beams according to the first embodiment. As shown in FIG. 7, in the comparative example using a simple E×B filter as the beam separator 214, after an image plane is formed at the position before reaching the beam separator 214, the multiple secondary electron beams 300 travels, while spreading, to the beam separator 214, the deflector 218, and the magnetic lens 224. Therefore, in the comparative example, the beam diameter D₁ of the entire multiple secondary electron beams 300 becomes wider at the position of the deflector 218. Moreover, at the position of the magnetic lens 224, the beam diameter D₂ of the entire multiple secondary electron beams 300 becomes further wider. The wider the beam diameter D₁ of the entire multiple secondary electron beams 300 becomes, the larger the aberration is generated by the deflector 218. Similarly, the wider the beam diameter D₂ of the entire multiple secondary electron beams 300 becomes, the larger the aberration is generated by the magnetic lens 224. In contrast, according to the first embodiment, since the multiple secondary electron beams 300 are refracted in the converging direction when they pass through the beam separator 214, the beam diameter d₁ of the entire multiple secondary electron beams 300 at the position of the deflector 218 can be smaller than the beam diameter D₁ of the comparative example. Therefore, the aberration generated by the deflector 218 can be suppressed or prevented. Similarly, at the position of the magnetic lens 224, the beam diameter d₂ of the entire multiple secondary electron beams 300 can be smaller than the beam diameter D₂ of the comparative example. Therefore, the aberration generated by the magnetic lens 224 can be suppressed or prevented.

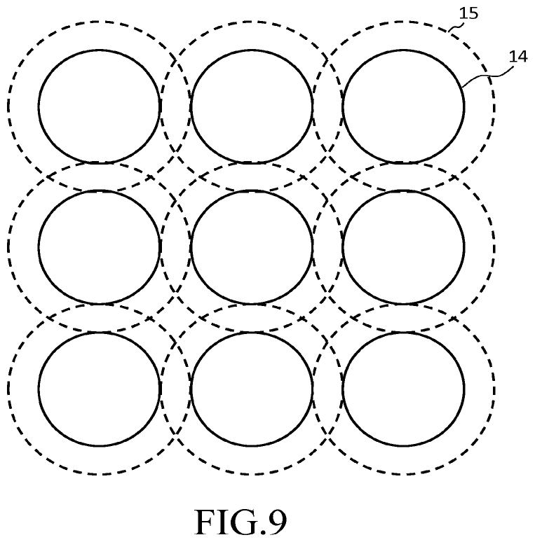

FIG. 9 is an illustration of an example of beam diameters of multiple secondary electron beams at the detection surface of a multi-detector according to the first embodiment and a comparative example. In the comparative example described above, since the aberration by the deflector 218 and the magnetic lens 224 becomes large, the beam diameter of each beam 15 of the multiple secondary electron beams 300 is large at the detection surface of the multi-detector 222. Consequently, as shown in FIG. 9, the beams 15 may overlap with each other. In contrast, according to the first embodiment, since the aberration by the deflector 218 and the magnetic lens 224 can be prevented, the beam diameter of each beam 14 of the multiple secondary electron beams 300 at the detection surface of the multi-detector 222 can be made small. As a result, as shown in FIG. 9, it is possible to avoid the mutual overlapping of the beams 14.

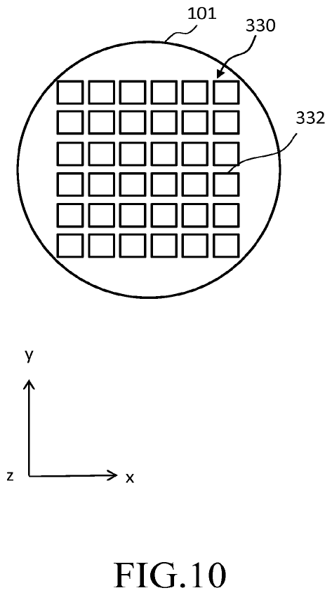

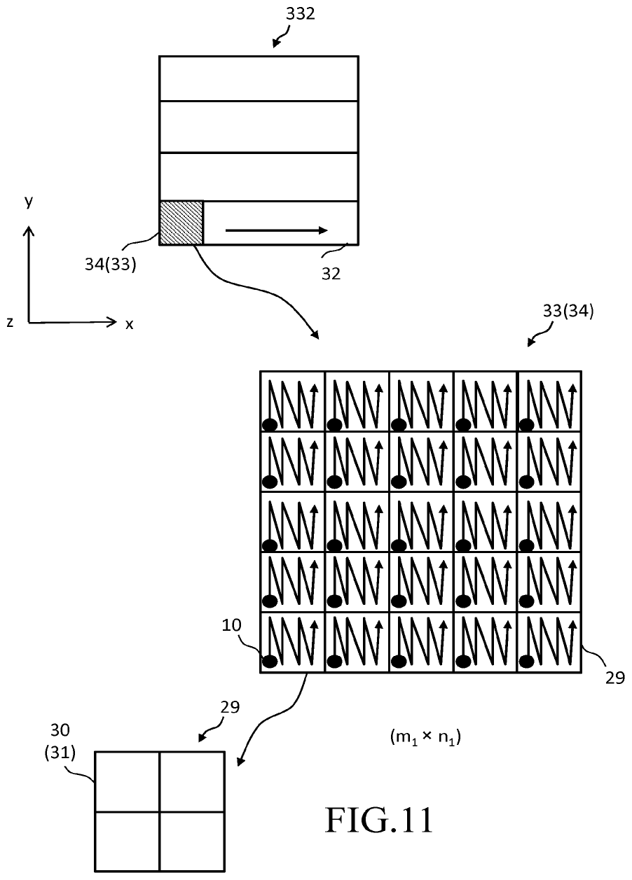

FIG. 10 is an example of a plurality of chip regions formed on a semiconductor substrate, according to the first embodiment. In FIG. 10, a plurality of chips (wafer dies) 332 are formed in a two-dimensional array in an inspection region 330 of the semiconductor substrate (wafer). With respect to each chip 332, a mask pattern for one chip formed on an exposure mask substrate is reduced to, for example, ¼, and exposed/transferred onto each chip 332 by an exposure device (stepper) (not shown).

FIG. 11 is an illustration describing image acquisition processing according to the first embodiment. As shown in FIG. 11, the region of each chip 332 is divided in the y direction into a plurality of stripe regions 32 by a predetermined width, for example. The scanning operation by the image acquisition mechanism 150 is carried out, for example, for each stripe region 32. The operation of scanning the stripe region 32 advances relatively in the x direction while the stage 105 is moved in the −x direction, for example. Each stripe region 32 is divided in the longitudinal direction into a plurality of rectangular regions 33. Beam application to a target rectangular region 33 is achieved by collectively deflecting all the multiple primary electron beams 20 by the main deflector 208.

FIG. 11 shows the case of multiple primary electron beams 20 of 5 rows by 5 columns. The size of an irradiation region 34 that can be irradiated by one irradiation with the multiple primary electron beams 20 is defined by (the x-direction size obtained by multiplying the x-direction beam pitch of the multiple primary electron beams 20 on the substrate 101 by the number of x-direction beams)×(the y-direction size obtained by multiplying the y-direction beam pitch of the multiple primary electron beams 20 on the substrate 101 by the number of y-direction beams). The irradiation region 34 serves as a field of view of the multiple primary electron beams 20. A sub-irradiation region 29, which is surrounded by the x-direction beam pitch and the y-direction beam pitch and in which the primary electron beam 10 concerned itself is located, is irradiated and scanned with each primary electron beam 10 of the multiple primary electron beams 20. Each primary electron beam 10 is associated with any one of the sub-irradiation regions 29 which are different from each other. At the time of each shot, each primary electron beam 10 is applied to the same position in the associated sub-irradiation region 29. The surface of the substrate 101 where a pattern has been formed is scanned with the multiple primary electron beams 20 collectively deflected by the sub deflector 209 (first deflector). In other words, the primary electron beam 10 is moved in the sub-irradiation region 29 by collective deflection of all of the multiple primary electron beams 20 by the sub deflector 209. By repeating this operation, one sub-irradiation region 29 is irradiated with one primary electron beam 10, in order.

Preferably, the width of each stripe region 32 is set to be the same as the y-direction size of the irradiation region 34, or to be the size reduced by the width of the scanning margin. In the case of FIG. 11, the irradiation region 34 and the rectangular region 33 are of the same size. However, it is not limited thereto. The irradiation region 34 may be smaller than the rectangular region 33, or larger than it. The sub-irradiation region 29, in which the primary electron beam 10 concerned itself is located, is irradiated and scanned with each primary electron beam 10 of the multiple primary electron beams 20. Then, when scanning of one sub-irradiation region 29 is completed, the irradiation position is moved to an adjacent rectangular region 33 in the same stripe region 32 by collective deflection of all the multiple primary electron beams 20 by the main deflector 208. By repeating this operation, the stripe region 32 is irradiated in order. After completing scanning of one stripe region 32, the irradiation region 34 is moved to the next stripe region 32 by moving the stage 105 and/or by collectively deflecting all of the multiple primary electron beams 20 by the main deflector 208. As described above, by irradiation with each primary electron beam 10, the scanning operation per sub-irradiation region 29 and acquisition of a secondary electron image are performed. By combining secondary electron images of respective sub-irradiation regions 29, a secondary electron image of the rectangular region 33, a secondary electron image of the stripe region 32, or a secondary electron image of the chip 332 is configured. When an image comparison is actually performed, the sub-irradiation region 29 in each rectangular region 33 is further divided into a plurality of frame regions 30, and a frame image 31 being a measured image of each frame region 30 is compared. FIG. 11 shows the case of dividing the sub-irradiation region 29 which is scanned with one primary electron beam 10 into four frame regions 30 by halving it in the x and y directions.

In the case of the substrate 101 being irradiated with the multiple primary electron beams 20 while the stage 105 is continuously moving, the main deflector 208 executes a tracking operation by performing collective deflection so that the irradiation position of the multiple primary electron beams 20 may follow the movement of the stage 105. Therefore, the emission position of the multiple secondary electron beams 300 changes every second with respect to the trajectory central axis of the multiple primary electron beams 20. Similarly, in the case of scanning the sub-irradiation region 29, the emission position of each secondary electron beam changes every second inside the sub-irradiation region 29. The deflector 218 collectively deflects the multiple secondary electron beams 300 so that each secondary electron beam whose emission position has changed may be applied to a corresponding detection region of the multi-detector 222. It is also preferable that an alignment coil, or the like, irrespective of the deflector 218, is arranged in the secondary electron optical system in order to correct the change of the emission position.

As described above, the image acquisition mechanism 150 proceeds with a scanning operation per stripe region 32. The multiple secondary electron beams 300 emitted from the substrate 101 due to irradiation with the multiple primary electron beams 20 is detected by the multi-detector 222 as described above. A reflected electron may be included in the detected multiple secondary electron beams 300. Alternatively, a reflected electron may diffuse during moving in the secondary electron optical system and therefore may not reach the multi-detector 222. Detected data (measured image data: secondary electron image data: inspection image data) on the secondary electron of each pixel in each sub-irradiation region 29, detected by the multi-detector 222, is output to the detection circuit 106 in order of measurement. In the detection circuit 106, the detected data in analog form is converted into digital data by an A-D converter (not shown), and stored in the chip pattern memory 123. Then, acquired measured image data is transmitted to the comparison circuit 108, together with information on each position from the position circuit 107.

Meanwhile, the reference image generation circuit 112 generates, for each frame region 30, a reference image corresponding to the frame image 31, based on design data serving as a basis of a plurality of figure patterns formed on the substrate 101. Specifically, it operates as follows: First, design pattern data is read from the storage device 109 through the control computer 110, and each figure pattern defined by the read design pattern data is converted into image data of binary or multiple values.

As described above, basic figures defined by the design pattern data are, for example, rectangles (including squares) and triangles. For example, there is stored figure data defining the shape, size, position, and the like of each pattern figure by using information, such as coordinates (x,y) of the reference position of the figure, lengths of sides of the figure, and a figure code serving as an identifier for identifying the figure type such as rectangles and triangles.

When design pattern data used as the figure data is input to the reference image generation circuit 112, the data is developed into data for each figure. Then, the figure code, the figure dimensions, and others indicating the figure shape of the figure data are interpreted. Then, it is developed into design pattern image data of binary or multiple values as a pattern to be arranged in squares in units of grids of predetermined quantization dimensions, and then is output. In other words, the reference image generation circuit 112 reads design data, calculates the occupancy of a figure in the design pattern, for each square obtained by virtually dividing the inspection region into squares in units of predetermined dimensions, and outputs n-bit occupancy data. For example, it is preferable to set one square as one pixel. Assuming that one pixel has a resolution of ½⁸(= 1/256), the occupancy rate in each pixel is calculated by allocating sub-regions, each having 1/256 resolution, which correspond to the region of a figure arranged in the pixel. Then, it is generated as occupancy rate data of 8 bits. Such squares (inspection pixels) may be commensurate with pixels of measured data.

Next, the reference image generation circuit 112 performs filtering processing on design image data of a design pattern which is image data of a figure, using a predetermined filter function. Thereby, it becomes possible to match the design image data being design side image data, whose image intensity (gray scale level) is represented by digital values, with image generation characteristics obtained by irradiation with the multiple primary electron beams 20. The generated image data for each pixel of a reference image is output to the comparison circuit 108.

In the comparison circuit 108, for each frame region 30, a position alignment is performed based on units of sub-pixels between the frame image 31 (first age), being an image to be inspected, and the reference image (second image) corresponding to the frame image concerned. For example, the position alignment can be performed using a least-squares method.

The comparison unit 108 compares the frame image 31 (first image) and the reference image (second mage). The comparison unit 108 compares them, for each pixel 36, based on predetermined determination conditions in order to determine whether there is a defect such as a shape defect. For example, if a difference in gray scale level for each pixel 36 is larger than a determination threshold Th, it is determined that there is a defect. Then, the comparison result may be output to the storage device 109, the monitor 117, or the memory 118, or alternatively, output from the printer 119.

In addition to the die-to-database inspection described above, it is also preferable to perform the die-to-die inspection which compares data of measured images acquired by imaging identical patterns at different positions on the same substrate. Alternatively, the inspection may be performed using only a measurement image.

As described above, according to the first embodiment, it is possible to suppress/prevent spreading of the multiple secondary electron beams 300 separated from the multiple primary electron beams 20. Therefore, aberration in subsequent steps in the optical systems can be reduced. As a result, overlapping of the multiple secondary electron beams 300 on the detection surface of the multi-detector 222 can be suppressed/prevented.

### Second Embodiment

In a second embodiment, the contents are the same as those of the first embodiment other than the internal configuration of the beam separator 214.

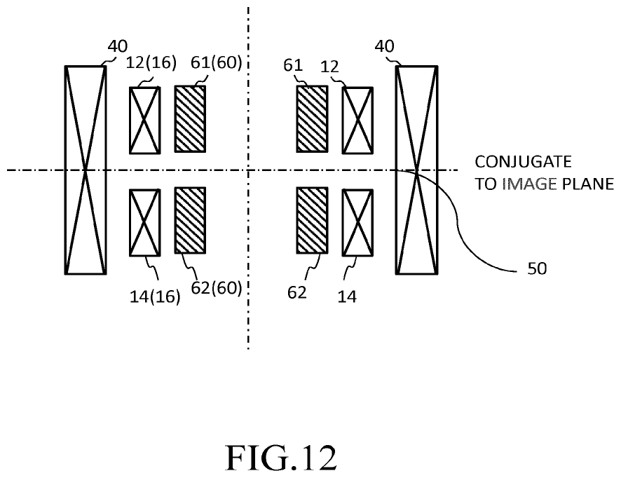

FIG. 12 is an illustration of a configuration of a beam separator according to the second embodiment. FIG. 12 shows a sectional view of the beam separator 214 of the second embodiment. In FIG. 12, the beam separator 214 includes magnetic lenses 40, a set of magnetic poles 16, and a set of electrodes 60. The set of magnetic poles 16 is arranged at the inner side from the magnetic lens 40. The set of electrodes 60 is arranged at the same height position as that of the set of magnetic poles 16. For example, the set of electrodes 60 is arranged at the inner side from the set of magnetic poles 16. A gap 50 (not shown) is formed at the intermediate height position of the magnetic lens 40. The set of magnetic poles 16 includes a set of multipolar magnetic poles 12 (first set of multipolar magnetic poles), being the upper stage, and a set of multipolar magnetic poles 14 (second set of multipolar magnetic poles), being the lower stage. Each set of the sets of the multipolar magnetic poles 12 and 14 is composed of two or more poles. For example, it is composed of four magnetic poles with phases mutually shifted by 90 degrees. Desirably, it is composed of eight magnetic poles.

The set of electrodes 60 includes a set of multipolar electrodes 61 (first set of multipolar electrodes), being the upper stage, and a set of multipolar electrodes 62 (second set of multipolar electrodes), being the lower stage. Each set of the sets of the multipolar electrodes 61 and 62 is composed of two or more poles. For example, it is composed of four electrodes with phases mutually shifted by 90 degrees. Desirably, it is composed of eight electrodes.

By the sets of multipolar magnetic poles 12 and 14 and the sets of multipolar electrodes 61 and 62, the magnetic field B and the electric field E are generated to be perpendicular to each other on the plane (plane of the x and y axes) perpendicular to the traveling direction (trajectory center axis; z axis) of the center beam of the multiple primary electron beams 20.

The intermediate height position between the set of the multipolar magnetic poles 12, being the first stage, and the set of the multipolar magnetic poles 14, being the second stage, is coincident with the intermediate height position of the magnetic lens 40. In other words, the set of the multipolar magnetic poles 12, being the first stage, and the set of the multipolar magnetic poles 14, being the second stage, are arranged symmetrically at the upper and lower sides of the magnetic field center position formed at the height position of the gap of the magnetic lens 40. Similarly, the intermediate height position between the set of the multipolar electrodes 61, being the first stage, and the set of the multipolar electrodes 62, being the second stage, is coincident with the intermediate height position of the magnetic lens 40. In other words, the set of the multipolar electrodes 61, being the first stage, and the set of the multipolar electrodes 62, being the second stage, are arranged symmetrically at the upper and lower sides of the magnetic field center position formed at the height position of the gap of the magnetic lens 40. In the example of FIG. 12, the set of multipolar magnetic poles 12 and the set of multipolar electrodes 61 are arranged at the same height position. However, it is not limited thereto. The height position of the set of multipolar magnetic poles 12 and that of the set of multipolar electrodes 61 may be shifted from each other. Similarly, in the example of FIG. 12, the set of multipolar magnetic poles 14 and the set of multipolar electrodes 62 are arranged at the same height position. However, it is not limited thereto. The height position of the set of multipolar magnetic poles 14 and that of the set of multipolar electrodes 62 may be shifted from each other.

A magnetic field whose magnetic field center is at the center height position of the set of multipolar magnetic poles 12 is generated by the set of multipolar magnetic poles 12. A magnetic field whose magnetic field center is at the center height position of the set of multipolar magnetic poles 14 is generated by the set of multipolar magnetic poles 14. By combining these two magnetic fields, a magnetic field B′ is generated whose magnetic field center is at the intermediate height position between the set of multipolar magnetic poles 12, being the first stage, and the set of multipolar magnetic poles 14, being the second stage. Similarly, an electric field E is generated whose electric field center is at the intermediate height position between the set of multipolar electrodes 61, being the first stage, and the set of multipolar electrodes 62, being the second stage. Then, a magnetic field B whose magnetic field center is at the intermediate height position of the magnetic lens 40 is formed by the magnetic lens 40. Therefore, each of the magnetic field B, the electric field E, and the magnetic field B′ is formed having its center position is at the same height position (position conjugate to the image plane).

In the beam separator 214, the multiple secondary electron beams 300 are separated from the multiple primary electron beams 20 by the sets of multipolar magnetic poles 12 and 14 and the sets of multipolar electrodes 61 and 62, and with that, the center secondary electron beam 301 of the multiple secondary electron beams 300 travels, while its spreading is suppressed or prevented by the lens action of the magnetic lens 40, to the deflector 218.

In the explanation described above, each “ . . . circuit” includes processing circuitry. The processing circuitry includes, for example, an electric circuit, computer, processor, circuit board, quantum circuit, semiconductor device, or the like. Each “ . . . circuit” may use common processing circuitry (the same processing circuitry), or different processing circuitry (separate processing circuitry). A program for causing a processor, etc. to execute processing may be stored in a recording medium, such as a magnetic disk drive, magnetic tape drive, FD, or ROM (Read Only Memory). For example, the position circuit 107, the comparison circuit 108, the reference image generation circuit 112, and others may be configured by at least one processing circuit described above.

Embodiments have been explained referring to specific examples described above. However, the present invention is not limited to these specific examples. For example, although the sets of multipolar magnetic poles 12 and 14, and the sets of multipolar electrodes 61 and 62 are configured by separate structures in the above examples, it is not limited thereto. For example, a magnetic field and/or an electric field may be applied to the same structure. In other words, it is acceptable that a magnetic pole itself functions as an electrode.

While the apparatus configuration, control method, and others not directly necessary for explaining the present invention are not described, some or all of them can be appropriately selected and used on a case-by-case basis when needed.

Further, any multi-electron beam image acquisition apparatus and multi-electron beam image acquisition method that include elements of the present invention and that can be appropriately modified by those skilled in the art are included within the scope of the present invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A multi-electron beam image acquisition apparatus comprising:
a multiple beam forming mechanism configured to form multiple primary electron beams;
a primary electron optical system configured to irradiate a target object surface with the multiple primary electron beams;
a beam separator, arranged at a position conjugate to an image plane of each primary electron beam of the multiple primary electron beams, configured to form an electric field and a magnetic field to be perpendicular to each other, to separate multiple secondary electron beams, emitted from the target object surface due to irradiation with the multiple primary electron beams, from the multiple primary electron beams by using actions of the electric field and the magnetic field, and to have a lens action on the multiple secondary electron beams in at least one of the electric field and the magnetic field;
a multi-detector configured to detect the multiple secondary electron beams; and
a secondary electron optical system configured to lead the multiple secondary electron beams to the multi-detector,
wherein the beam separator includes
a magnetic lens,
a first set of multipolar magnetic poles, being a first stage (upper stage), composed of at least two poles,
a second set of multipolar magnetic poles, being a second stage (lower stage), composed of at least two poles, and
a set of electrodes arranged between poles of the first set of the multipolar magnetic poles and poles of the second set of the multipolar magnetic poles, the first set of the multipolar magnetic poles and the second set of the multipolar magnetic poles being arranged symmetrically at upper and lower sides of a magnetic field center position of the magnetic lens.

2. The apparatus according to claim 1 further comprising:
a deflector configured to deflect the multiple secondary electron beams separated from the multiple primary electron beams.

3. The apparatus according to claim 1, wherein each electrode of the set of electrodes is arranged at an intermediate height position between the poles of the first set of the multipolar magnetic poles and the poles of the second set of the multipolar magnetic poles, which are symmetrically at the upper and lower sides.

4. The apparatus according to claim 1, wherein the set of electrodes is arranged at a height position of a center of a magnetic field of the electromagnetic lens.

5. A multi-electron beam image acquisition apparatus comprising:
a multiple beam forming mechanism configured to form multiple primary electron beams;
a primary electron optical system configured to irradiate a target object surface with the multiple primary electron beams;
a beam separator, arranged at a position conjugate to an image plane of each primary electron beam of the multiple primary electron beams, configured to form an electric field and a magnetic field to be perpendicular to each other, to separate multiple secondary electron beams, emitted from the target object surface due to irradiation with the multiple primary electron beams, from the multiple primary electron beams by using actions of the electric field and the magnetic field, and to have a lens action on the multiple secondary electron beams in at least one of the electric field and the magnetic field;
a multi-detector configured to detect the multiple secondary electron beams; and
a secondary electron optical system configured to lead the multiple secondary electron beams to the multi-detector,
wherein the beam separator includes
a magnetic lens,
a first set of multipolar magnetic poles, being a first stage, composed of at least two poles,
a second set of multipolar magnetic poles, being a second stage, composed of at least two poles,
a first set of multipolar electrodes, being a first stage, composed of at least two poles, arranged at a same height position as that of the first set of the multipolar magnetic poles, and
a second set of multipolar electrodes, being a second stage, composed of at least two poles, arranged at a same height position as that of the second set of the multipolar magnetic poles.

6. A multi-electron beam image acquisition method comprising:
irradiating a target object surface with multiple primary electron beams;
separating, at a position conjugate to an image plane of each primary electron beam of the multiple primary electron beams, multiple secondary electron beams, which were emitted from the target object surface due to the irradiating with the multiple primary electron beams, from the multiple primary electron beams, and refracting the multiple secondary electron beams in a converging direction at the position conjugate to the image plane;
further refracting the multiple secondary electron beams which have been separated from the multiple primary electron beams and refracted in the converging direction at the position conjugate to the image plane, in the converging direction at a position away from a trajectory of the multiple primary electron beams; and
detecting the multiple secondary electron beams which have been refracted at the position away from the trajectory of the multiple primary electron beams,
wherein the multiple secondary electron beams are separated from the multiple primary electron beams and refracted in the converging direction at the position conjugate to the image plane by using a beam separator including
a magnetic lens,
a first set of multipolar magnetic poles, being a first stage (upper stage), composed of at least two poles,
a second set of multipolar magnetic poles, being a second stage (lower stage), composed of at least two poles, and
a set of electrodes arranged between poles of the first set of the multipolar magnetic poles and poles of the second set of the multipolar magnetic poles, the first set of the multipolar magnetic poles and the second set of the multipolar magnetic poles being arranged symmetrically at upper and lower sides with respect to a magnetic field center position of the magnetic lens.

7. The method according to claim 6, further comprising:
deflecting the multiple secondary electron beams separated from the multiple primary electron beams.

8. A multi-electron beam image acquisition method comprising:
irradiating a target object surface with multiple primary electron beams;
separating, at a position conjugate to an image plane of each primary electron beam of the multiple primary electron beams, multiple secondary electron beams, which were emitted from the target object surface due to the irradiating with the multiple primary electron beams, from the multiple primary electron beams, and refracting the multiple secondary electron beams in a converging direction at the position conjugate to the image plane;
further refracting the multiple secondary electron beams which have been separated from the multiple primary electron beams and refracted in the converging direction at the position conjugate to the image plane, in the converging direction at a position away from a trajectory of the multiple primary electron beams; and
detecting the multiple secondary electron beams which have been refracted at the position away from the trajectory of the multiple primary electron beams,
wherein the multiple secondary electron beams are separated from the multiple primary electron beams and refracted in the converging direction at the position conjugate to the image plane by using a beam separator including
a magnetic lens,
a first set of multipolar magnetic poles, being a first stage, composed of at least two poles,
a second set of multipolar magnetic poles, being a second stage, composed of at least two poles,
a first set of multipolar electrodes, being a first stage, composed of at least two poles, arranged at a same height position as that of the first set of the multipolar magnetic poles, and
a second set of multipolar electrodes, being a second stage, composed of at least two poles, arranged at a same height position as that of the second set of the multipolar magnetic poles.
